(19) United States
(12) Patent Application Publication
(10) Pub. No.: US 2015/0279636 A1
(43) Pub. Date: Oct. 1, 2015

(54) PARTICLE FREE ROTARY TARGET AND METHOD OF MANUFACTURING THEREOF

(71) Applicant: APPLIED MATERIALS, INC., Santa Clara,, CA (US)

(72) Inventor: Aki Hosokawa, Sunnyvale, CA (US)

(21) Appl. No.: 14/434,066

(22) PCT Filed: Oct. 4, 2013
(86) PCT No.: PCT/US2013/063504

§ 371 Date: Apr. 7, 2015

Related U.S. Application Data
(60) Provisional application No. 61/711,691, filed on Oct. 9, 2012.

(51) Int. Cl. H01J 37/34

(52) U.S. Cl. CPC H01J 37/3417; H01J 37/3426; H01J 37/3435; H01J 37/3491

(57) ABSTRACT

A rotatable sputter target configured for rotation around an axis defining an axial direction is described. The rotatable sputter target includes at least a first target segment and a second target segment forming a target, wherein at least one of opposing side surfaces of the first target segment and the second target segment are roughened, particularly to a surface roughness of 10 μm Rmax or above, more particularly of 100 μm Rmax or above

### TECHNICAL FIELD OF THE INVENTION

Embodiments of the present invention relate to rotatable sputter targets and rotatable sputter cathodes. Embodiments of the present invention particularly relate to rotatable sputter targets and rotatable sputter cathodes, wherein two or more segments are provided to form the target. Specifically they relate to rotatable sputter targets configured for rotation around an axis defining an axial direction, rotatable sputter cathodes and methods for manufacturing a rotatable sputter cathode.

### BACKGROUND OF THE INVENTION

In many applications it is desired to deposit thin layers on a substrate. Known techniques for depositing thin layers are, in particular, evaporating, chemical vapor sputtering and sputtering deposition. For example, sputtering can be used to deposit a thin layer such, as a thin layer of ceramics. During the sputtering process, the coating material is transported from a sputtering target consisting of that material to the substrate to be coated by bombarding the surface of the target with ions. During a sputtering process, a target may be electrically biased so that ions generated in a process region may bombard the target surface with sufficient energy to dislodge atoms of target material from the target surface. The sputtered atoms may deposit onto a substrate that may be grounded to function as an anode. Alternatively, the sputtered atoms may react with a gas in the plasma, for example nitrogen or oxygen, to deposit onto the substrate in a process called reactive sputtering.

Direct current (DC) sputtering and alternating current (AC) sputtering are forms of sputtering in which the conductive target may be biased to attract ions towards the target. When the sputtering target is non-conductive, middle frequency (MF) sputtering and radio frequency (RF) sputtering may be used. The sides of the sputtering chamber may be covered with a shield to protect the chamber walls from deposition during sputtering, and also act as an anode to capacitively couple the target power to the plasma generated in the sputtering chamber. Sputtering is now being applied to the fabrication of flat panel displays (FPDs) based upon thin film transistors (TFTs). FPDs are typically fabricated on thin rectangular sheets of glass. The electronic circuitry formed on the glass panel is used to drive optical circuitry, such as liquid crystal displays (LCDs), organic LEDs (OLEDs), or plasma displays subsequently mounted on or formed in the glass panel. Yet other types of flat panel displays are based upon organic light emitting diodes (OLEDs). Other types of substrates are being contemplated, for example, flexible polymeric sheets. Similar techniques can be used in fabricating solar cells.

There are two general types of sputtering targets, planar sputtering targets and rotary sputtering target assemblies. Both planar and rotary sputtering target assemblies have their advantages. Due to the geometry and design of the cathodes, rotatable targets typically have a higher utilization and an increased operation time than planar ones. Rotary sputtering target assemblies may be particularly beneficial in large area substrate processing. Bonding a cylindrical target tube to a backing tube is a challenge in the fabrication of robot rotary target assemblies. This is particularly true for target materials which cannot be provided in a sufficiently large enough size to provide a single-piece target, and where target segments need to be placed adjacent to each other to form the target for sputtering.

Many rotatable sputtering cathodes typically include a cylindrical rotatable tube, e.g. a backing tube, having a layer of the target material applied to the outer surface thereof. In the manufacture of such rotatable sputtering cathodes, the target material may, for example, be applied by spraying onto, casting or isostatic pressing of powder onto the outer surface of a backing tube. Alternatively, a hollow cylinder of a target material, which may also be referred to as a target tube, may be arranged on and bonded, e.g. with indium, to the backing tube for forming a rotatable target.

In order to obtain increased deposition rates, the use of magnetically enhanced cathodes has been proposed. This may also be referred to as magnetron sputtering. Magnetic means, which may include an array of magnets, may be arranged inside the sputtering cathode, e.g. inside the backing tube, and provide a magnetic field for magnetically enhanced sputtering. The cathode is typically rotatable about its longitudinal axis so that it can be turned relative to the magnetic means.

The target material of typical sputtering targets may be depleted or consumed quickly, e.g. within a week, during sputtering. A major portion of operating costs of sputtering installations is target costs. Accordingly, there is an ongoing need for improved and/or more cost-efficient rotatable targets.

Indium Tin Oxide (ITO) targets are difficult to make in larger sizes. Hence, the target is usually provided with a segmented design, i.e. several segments of the target material are provided to form the target. However, at the joint or interface of neighboring segments, particles can be generated. Particles can be generated in or adjacent to this joint or gap between two target segments since unsecured particles tend to accumulate in this area due to scattering and/or re-deposition. Besides the fact that particle generation can be harmful for the quality of the deposition process, counter measures like clean sputtering of a target also result in decreased target consumption or at least desired target consumption. Further, this results in a tendency to not fully use the target to the maximum extent.

In view of the above, it is an object of the present invention to provide a rotatable target and/or a rotatable cathode that overcomes at least some of the problems in the art.

### SUMMARY OF THE INVENTION

In light of the above, a rotatable sputter target configured for rotation around an axis defining an axial direction according to independent claim 1, a rotatable sputter cathode according to claim 10, and a method of manufacturing a rotatable sputter cathode according to independent claim 13 are provided.

According to one embodiment, a rotatable sputter target configured for rotation around an axis defining an axial direction is provided. The rotatable sputter target includes at least a first target segment and a second target segment forming a target, wherein a first outer radius of the first target segment differs from a second outer radius of a second target segment by 0.5 mm or more, particularly by 0.5 mm to 3 mm, more particularly by 1 mm to 1.5 mm.

According to another embodiment, a rotatable sputter cathode is provided. The cathode includes a backing tube and a rotatable sputter target configured for rotation around an axis defining an axial direction. The rotatable sputter target includes at least a first target segment and a second target segment forming a target, wherein a first outer radius of the first target segment differs from a second outer radius of the second target segment by 0.5 mm or more, particularly by 0.5 mm to 3 mm, more particularly by 1 mm to 1.5 mm.

According to a further embodiment, a method of manufacturing a rotatable sputter cathode is provided. The method includes attaching a first target segment to a backing tube at a first axial position, and attaching a second target segment to the backing tube adjacent to the first target segment and at a second axial position, wherein a step in the outer surface of the target formed by the first target segment and the second target segment is provided, wherein the step has a height of at least 0.5 mm, particularly of 0.5 mm to 3 mm, more particularly of 1 mm to 1.5 mm.

According to one embodiment, a rotatable sputter target configured for rotation around an axis defining an axial direction is provided. The rotatable sputter target includes at least a first target segment and a second target segment forming a target, wherein a first outer radius of the first target segment differs from a second outer radius of the second target segment by 0.5 mm or more, particularly by 0.5 mm to 3 mm, more particularly by 1 mm to 1.5 mm, and particularly wherein the first outer radius is at a first axial position of the target, which is adjacent to a second axial position of the second outer radius. Such an embodiment relating to a target or cathode respectively can be modified to yield yet further embodiments using features of other embodiments described herein.

According to yet further embodiments, a rotatable sputter target configured for rotation around an axis defining an axial direction and/or a corresponding rotatable sputter cathode as well as a method of manufacturing thereof are provided. The rotatable sputter target includes at least a first target segment and a second target segment forming a target, wherein the first target segment has a first radially outer surface, a first radially inner surface and two first opposing side surfaces, particularly two first opposing ring-shaped side surfaces, wherein the second target segment has a second radially outer surface, a second radially inner surface and two second opposing side surfaces, particularly two second opposing ring-shaped side surfaces, wherein at least the one side surface of the first side surfaces of the first target segment being provided adjacent to the one side surface of the second side surfaces of the second target segment has a surface roughness of 10 μm Rmax or above, particularly of 100 μm Rmax or above. Such an embodiment relating to a target or cathode respectively can be modified to yield yet further embodiments using features of other embodiments described herein.

According yet further embodiments, a rotatable sputter target configured for rotation around an axis defining an axial direction and/or a corresponding rotatable sputter cathode as well as a method of manufacturing thereof are provided. The rotatable sputter target includes at least a first target segment and a second target segment forming a target, wherein opposing side surfaces of the first target segment and the second target segment are roughened, particularly to a surface roughness of 10 μm Rmax or above, more particularly of 100 μm Rmax or above. Such an embodiment relating to a target or cathode respectively can be modified to yield yet further embodiments by features of other embodiments described herein.

Further aspects, advantages, and features of the present invention are apparent from the dependent claims, the description, and the accompanying drawings.

Embodiments are also directed at apparatuses manufactured by the disclosed methods and include apparatus parts resulting from each described method step. Furthermore, embodiments according to the invention are also directed to methods by which the described apparatus is manufactured or operates. It includes method steps for providing every feature of the apparatus.

### BRIEF DESCRIPTION OF THE DRAWINGS

So that the manner in which the above recited features of the present invention can be understood in detail, a more particular description of the invention, briefly summarized above, may be had by reference to embodiments. The accompanying drawings relate to embodiments of the invention and are described in the following:

FIG. 1 shows schematically a rotatable sputter cathode and a rotatable sputter target having a plurality of target segments according to embodiments described herein;

FIG. 2 shows schematically another rotatable sputter cathode and another rotatable sputter target having a plurality of target segments according to embodiments described herein;

FIG. 3 shows schematically a segment of a rotatable sputter target according to embodiments described herein;

FIG. 4 shows schematically a deposition apparatus having rotatable sputter cathodes and rotatable sputter targets provided therein, wherein the targets have a plurality of target segments according to embodiments described herein;

FIG. 5 shows schematically a further deposition apparatus having rotatable sputter cathodes and rotatable sputter targets provided therein, wherein the targets have a plurality of target segments according to embodiments described herein; and

FIG. 6 shows a flow chart for illustrating a method of manufacturing a rotatable sputter cathode according to embodiments described herein.

### DETAILED DESCRIPTION OF EMBODIMENTS

Reference will now be made in detail to the various embodiments of the invention, one or more examples of which are illustrated in the figures. Within the following description of the drawings, the same reference numbers refer to the same components. Generally, only the differences with respect to individual embodiments are described. Each example is provided by way of explanation of the invention and is not meant as a limitation of the invention. Further, features illustrated or described as part of one embodiment can be used on or in conjunction with other embodiments to yield yet a further embodiment. It is intended that the description includes such modifications and variations.

Furthermore, in the following description, a reference is made to a target segment of a rotatable target. It is understood that a target segment can also be referred to as a tile or target tile. Thereby, the one or more targets, for example four to eight or even more targets, can be provided in axial direction adjacent to each other to form the target. Thereby, the target, as well as the target segments, are configured to rotate around the axis, i.e. the rotational axis, during the sputtering process. Further, it is referred to a rotatable target as well as a rotatable cathode. Thereby, it is to be understood that the target comprises the target material to be deposited on the substrate. The cathode typically includes the target as well as a backing tube (if present) and can further include a magnet assembly inside the target or backing tube for magnetron sputtering. According to yet further modifications, the cathode may also include cooling channels for cooling the magnet assembly inside the backing tube and/or for cooling the backing tube. Accordingly, the rotatable target includes the material to be sputtered as such, and the target can be a portion of the rotatable cathode, which is typically utilized in a deposition system and for the sputtering process.

Embodiments of the present invention generally comprise a rotatable target, which can for example be a cylindrical target assembly, a method and apparatus for manufacturing a sputtering target or sputtering cathode. Thereby, the target or a corresponding cathode is provided with target segments and the target segments are improved for reduction of free particles at the interface or gape between the segments. Typically, at least one of these four measures is provided: a step in radial dimension between neighboring target segments, a roughened target segment side surface, i.e. the side surface of the segment facing a neighboring side surface of another segment, a reduced target joined gap, and an increase target length along the axial direction, i.e. the direction of the rotation axis. The sputtering target assembly or the rotatable target may be used in a PVD chamber, such as a PVD chamber available from AKT®, a subsidiary of Applied Materials, Inc., Santa Clara, Calif. or a PVD chamber available from Applied Materials Gmbh & Co. KG, located at Alzenau, Germany. However, it should be understood that the sputtering target assembly may have utility in other PVD chambers, including those chambers configured to process large area substrates, substrates in the form of continuous webs, large area round substrates and those chambers produced by other manufacturers.

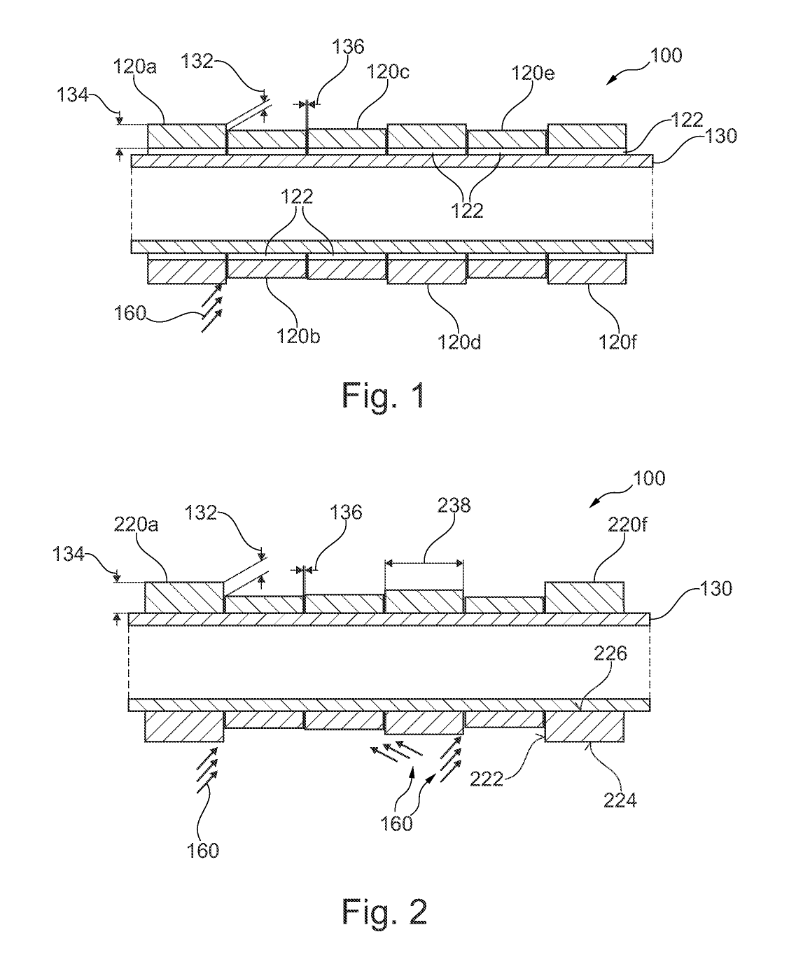

FIG. 1 shows a rotatable cathode 100. Several target segments 120a to 120f, which are generally referred to by reference numeral 120 below, are bonded by a bonding layer 122 to the backing tube 130. As can be seen, the target or the cathode, respectively, includes 6 target segments 120. However, according to yet further embodiments, which can be combined with other embodiments described herein, another number of segments can be provided. Typically, the number of targets depends on the length in the axial direction of the target segments and the length of the complete target. According to typical embodiments, which can be combined with other embodiments described herein, the length of at least one, typically of all target segments 120 of the cathode 100 is 300 mm or above typically from 400 mm to 600 mm. Thereby, compared to commonly used shorter target segments of 200 mm length, the number of target joined gaps can be reduced. Accordingly, the problem of free particles generated at the joined gap can also be reduced by reducing the number of joint gaps. The corresponding length of the target segments is shown by reference numeral 238 in FIG. 2.

The rotatable target segments have a thickness in the radial direction which is exemplarily indicated by reference numeral 134 for target segment 120a in FIG. 1. As can be seen, according to embodiments described herein, the target thickness can vary from target segment to target segment. Accordingly, the target segment thickness of segment 120a is different as compared to the target segment thickness of target 120b. The target segment thickness of segment 120b is different as compared to the target segment thickness of target 120c. The target segment thickness of segment 120c is different as compared to the target segment thickness of target 120d, and so on. Thus, between adjacent or neighboring target segments a thickness increase indicated by step 132 is provided. In other words, the outer diameter or outer radius of the target segments varies when considering an axial end position of one segment to the adjacent axial end position of the neighboring target.

Thereby, according to different embodiments, which can be combined with other embodiments described herein, the variation of the outer radius or the thickness of the target segments can be described by the slope of the outer surface position as a function of the axial position. For example, a first axial position P [mm] can be provided by an axial position of a first target segment, where the outer radius has a value R1 [mm]. At an axial position P+0.5 mm, the outer radius is varied, such that R2=R1+1 mm. Accordingly, the slope of the function defining the outer radius between the two axial positions P and P+0.5 is 2. According to typical embodiments, the slope can be at least 2 or above, typically at last 3 or above, even more typically at least 5 or above.

Thereby, FIGS. 1 and 2 refer to cylindrical targets where the outer radius of the target segments is essentially constant along the length of each target segment. That is, the target segments form a cylinder with the base surface being an annulus. Yet, according to alternative embodiments, which can be combined with other embodiments described herein, the target segments can also have a conically shaped outer surface or another variation in diameter or radius of the outer surface along the axial direction. Thereby, it would, for example, be possible that there are a plurality of similar target segments with a larger diameter at one end, and a smaller, second diameter at the opposing axial end of the segment. Accordingly, a neighboring target segment provided with the similar orientation would have the larger diameter of the neighboring segment adjacent to the smaller, second diameter of the first target segment, wherein a step would also be generated.

FIGS. 1 and 2 and the modifications thereof, which are described above, refer to a change in diameter of the outer target surface and/or a change in target thickness at each joint gap between adjacent target segments. Yet, it is to be understood, that a respective change in diameter of the outer target surface and/or the change in target thickness can be provided only at one or more joint gaps within the target or cathode 100. According to typical embodiments, the change in diameter of the outer target surface and/or the change in target thickness can be provided at at least 30% or 50% of the joint gaps existing in the target or the cathode, respectively.

The functioning of the change in diameter of the outer target surface and/or the change in target thickness can be understood with respect to the scattered particles referred to by reference numeral 160 in FIGS. 1 and 2. Particles being scattered in the plasma are directed towards the target surface to release target material upon impingement thereof. Particles, which are directed in directions, shown by the exemplary particles denoted with reference numerals 160, do not impinge on the joint gap between the target segments. Thereby, these scattered particles cannot accumulate at the joint gap and/or cannot release free particles that have been accumulated at the joint gap, wherein the release of the accumulated particles from the joint gap can be harmful to the deposition. Accordingly, as one angular direction is blocked in light of the step between the target segments, accumulation of particles and/or release of the particles accumulated in the joint gap or at the joint gap can be reduced by about 50% as the two directions (from left and right) in FIGS. 1 and 2 have about the same probability. If the number of target joint gaps is also reduced by 50% due to an increase in target length by a factor of 2, the problem to be solved can also be reduced by 75%.

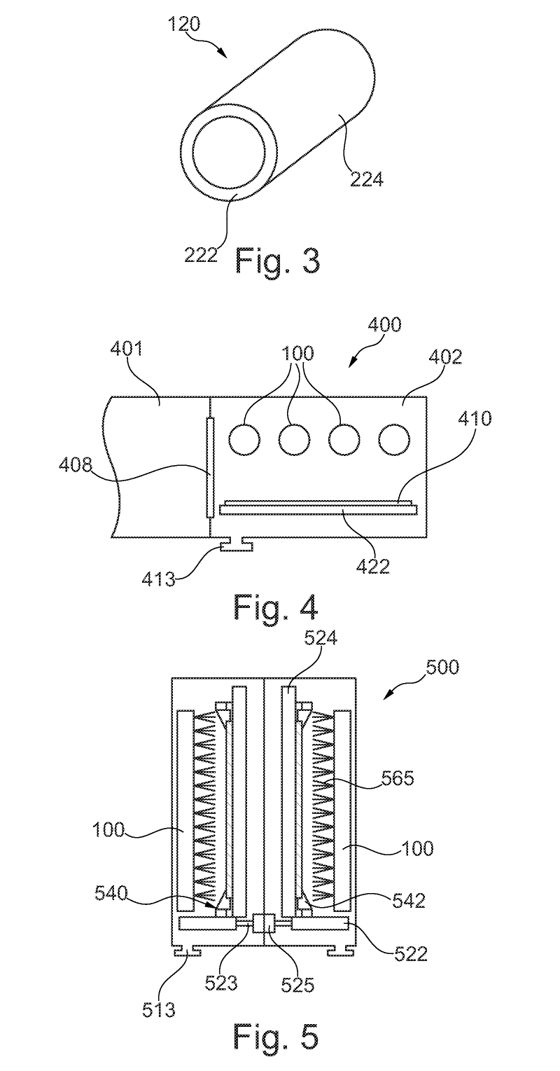

A further improvement can be provided by roughening the surface side walls of the target segments. An exemplary target segment is shown in FIG. 3. The target segment has an outer surface 224 and a side surface 222. A further surface, that is the inner surface of the cylinder 226 with the annulus-shaped base form, is shown in FIG. 2. The vertical wall, i.e the side surface 222 of the target segment joint area has a rough surface to mechanically interlock the particles, which accumulate at the joint gap between two segments. According to typical embodiments, one or both of the two opposing ring-shaped or annulus-shaped side surfaces of neighboring segments have a surface roughness of 10 μm Rₘₐₓ or above, particularly of 100 μm Rₘₐₓ or above. Thereby, a mechanical interlock for particles that have been accumulated at the joint gap is generated further reducing the problem of free particles from the joint gap to below 75%. For example, according to yet further modifications, edges or side surfaces of the segments or tiles may be roughened, as described above, by bead blasting. Advantageously, according to yet further embodiments, the opposed sides of the tiles or segments are bead blasted or otherwise roughened, preferably prior to bonding. As a result, any sputter material redeposited on the opposed sides adheres better to the sides 222 of the tiles or segments 120 to reduce or delay the flaking. The bead blasting may be performed by entraining hard particles, for example, of silica or silicon carbide, in a high pressure gas flow directed at the tile to roughen its surface.

According to yet further embodiments, which can be combined with other embodiments described herein, the joint gap between target segments can be provided such that the joint gap denoted by reference numeral 136 in FIGS. 1 and 2 is 0.3 mm or below, typically 0.1 mm to 0.3 mm. This can result in a yet further improvement.

Accordingly, several aspects have been mentioned namely the herein-described change in radius at the segment joint gap, the length of the segments in axial direction, the rough surface side surface of the segments and the dimension of the joint gap, to reduce the release of free particles during sputtering which have been accumulated at or in the joint gap. It is to be understood that all of these measures can be used independently from each other. Yet, beneficially all of these measures are used. Further, at least the change in target thickness at the joint gap in combination with the increased segment length, at least the roughened target segment side surface in combination with the increased segment length, or at least the change in target thickness at the joint gap in combination with the increased segment length and the roughened target segment side surface can be utilized. Thereby, embodiments can reduce particle release from the joint gap. The release of the undesired particles, which are reduced by the embodiments described herein, can be generated as follows. Due to the segmented design of the target, unsecured particles have a tendency to accumulate in the target segment area, i.e. the target segment joint. Unsecured particles are generated by re-deposition or material scattering. In order to minimize the amount of unsecured particles and/or the amount of unsecured particles released, the embodiments provide: a step at the target joint area to reduce the particle entrance of scattered particles to this area, a vertical wall of the target joint area having a rough surface to mechanically interlock the particle, a target joint gap length minimized to 0.1-0.3 mm, and a target segment length, which is about twice as long to reduce the number of target joint area.

According to different embodiments, which can be combined with other embodiments described herein, the target material can be selected from the group consisting of: a ceramic, a metal, ITO, IZO, IGZO, AZO, SnO, AlSnO, InGaSnO, titanium, aluminum, copper, molybdenum, and combinations thereof. Thereby, the target material is typically provided either by the material to be deposited on a substrate or by the material which is supposed to react with a reactive gas in the processing area to then be deposited on the substrate after reacting with the reactive gas.

FIG. 2 shows a rotatable cathode 100. Several target segments 220a to 220f, which are generally referred to by reference numeral 220 below, are provided at the backing tube 130. Thereby, the target is provided as a non-bonded target. According to typical embodiments described herein, the target segments, which are bonded as shown with respect to FIG. 1, can also be provided as non-bonded targets. Thereby, the target segments can be shrink-fitted to the backing tube or can be provided with a small distance to the backing tube. Typically, bonding targets are used because non-bonded targets are more difficult to manufacture, particularly for brittle materials. However, the herein-described embodiments can also be provided for non-bonded targets.

As can be seen in FIG. 2, the target or the cathode, respectively, includes 6 target segments 220. However, according to yet further embodiments, which can be combined with other embodiments described herein, another number of segments can be provided. Typically, the number of targets depends on the length in the axial direction of the target segments and the length of the complete target. According to typical embodiments, which can be combined with other embodiments described herein, the length of at least one, typically of all, target segments 120 of the cathode 100 is 300 mm or above, typically from 400 mm to 600 mm. Thereby, according to commonly used shorter target segments of 200 mm, the number of target joined gaps can be reduced. Accordingly, the problem of free particles generated at the joined gap can also be reduced by reducing the number of joint gaps. The corresponding length of the target segments is shown by reference numeral 238.

According to yet further embodiments, which can be combined with other embodiments described herein, the target and the cathode as shown and described with respect to FIG. 2 can have similar modifications as the targets and embodiments described with respect to FIG. 1. Accordingly, in the following, only further modifications from the targets and cathodes described with respect to FIG. 1 are described.

According to yet further embodiments, which can be combined with other embodiments described herein, the target segments, which are provided at one or both ends of the target in axial direction can be provided with an increased target thickness 134 as illustrated in FIG. 2. In FIG. 2 the target segment at the far left end of the target and the target segment at the far right end of the target segment are provided with an increased thickness as compared to FIG. 1. Thereby, for embodiments described herein, a target shape, which corresponds to a so-called dog-bone target for cylindrical targets, is provided. The increased target thickness for target segments at the axial ends of the target has the advantage that an increased target consumption in these areas can be compensated for. Accordingly, the overall target usage can be increased.

Commonly a target thickness can be about 9 mm and a target is exchanged when the remaining target thickness at the axial position with the minimal target thickness is about 1 mm. Thereby, it is avoided that the bonding material or the backing tube is sputtered, which would be a failure of the desired deposition process. Using increased initial target thicknesses at the end portions of the target allows for a longer use of the target because the amount or number of axial positions, at which the minimal target thickness is achieved is increased, or because the average target thickness is reduced at the time the first position reaches a critical thickness threshold, e.g. 1 mm. Accordingly, by increasing the target segment thickness at the end portions of the target, the overall usage can be increased. Further, the reduced necessity to clean sputter the target, i.e. clean the target from accumulated particles in the joint gaps by sputtering on a dummy substrate or in a direction without a substrate for manufacturing thin-films is reduced. Thereby, as compared to conventional targets, embodiments described herein allow for a target usage of up to 90%.

According to some embodiments, which can be combined with other embodiments described herein, a thicker target segment and/or an increased target diameter step can be located at the deepest erosion area, for example at the axial ends of the target. Hence, the target life can be up to 30% longer when compared with conventional targets.

According to yet further embodiments, which can be combined with other embodiments described herein, the backing tube 130 may be fabricated from a rigid material such as stainless steel, titanium, aluminum, and combinations thereof. The bonding material 122 shown in FIG. 1 is a material suitable for bonding sputtering targets to backing plates or tubes. Examples of suitable bonding materials include, but are not limited to: indium based bonding material, such as indium and indium alloys. Additionally, within the target assembly, one or more magnetrons (not shown) may be provided. The magnetrons may rotate within the center of the target assembly. Additionally, cooling mechanisms (also not shown), such as cooling fluid tubes, may be disposed within target assembly 100. The target assembly 100 is rotatable about an axis of the target or cathode to promote uniform target erosion when in use.

FIG. 4 is used to describe a first plurality of embodiments of a deposition apparatus 400. The deposition apparatus has at least a deposition chamber 402, which can be configured to be evacuated. For example, the deposition chamber has a vacuum flange 413. A pumping system (not shown) can be connected to the chamber 402 for providing a technical vacuum in the chamber. Typically, the vacuum can be provided as desired for the sputtering process. A typical process pressure may be between 1×10⁻³ and 10×10⁻³ mbar.

A substrate support 422 can be provided in the chamber 402. The substrate support supports the substrate 410 during deposition of a layer or thin film on the substrate by the cathodes 100. In the example shown in FIG. 4, four cathodes are provided. The cathodes are biased with respect to an anode and/or with respect to the chamber walls 402. Further, the substrate or the substrate support 422 can be biased for deposition of the layer thereon.

According to typical embodiments, the cathodes can be provided as pairs of cathodes, e.g. rotatable MF Twin-cathodes. For ceramic targets like ITO, a DC sputtering process can be provided, wherein the cathodes are biased to a DC voltage. Thereby, according to typical embodiments, sputtering from a silicon target, an aluminum target, a molybdenum target or the like is conducted by MF sputtering, that is middle frequency sputtering. According to embodiments herein, middle frequency is a frequency in the range 5 kHz to 100 kHz, for example, 10 kHz to 50 kHz. Sputtering from a target for a transparent conductive oxide film is typically conducted as DC sputtering.

According to different alternatives, the substrate support 422 in the chamber 402 can be a support pedestal, wherein the substrate 410 is provided on the pedestal with an actuator such as a robot arm. Alternatively, the substrate support can be a part of a substrate transport system, wherein rollers are provided to transport the substrate into and out of the chamber 402. The roller system can guide a substrate or a carrier, which in turn carries a substrate therein.

Moreover, as a yet further alternative, in the event of a transport system, the substrate can also be deposited in an in-line process. In an in-line process the substrate is moved through the chamber 402 while being deposited. In such a case, a chamber opening having a valve unit 408 or the like as shown on the left hand side of the chamber 402 would also be provided on the right hand side of chamber 402. Further, typically, another chamber would be provided on the side of chamber 402 opposing the chamber 401. According to typical embodiments, chamber 401 can be a load-lock chamber, a transfer chamber, e.g. including a robot or can be an adjacent processing chamber, e.g. for deposition, etching, heating or the like.

According to some embodiments, which can be combined with other embodiments described herein, the embodiments described herein can be utilized for Display PVD, i.e. sputter deposition on large area substrates for the display market. According to some embodiments, large area substrates or respective carriers, wherein the carriers have a plurality of substrates, may have a size of at least 0.67 m². Typically, the size can be about 0.67 m² (0.73×0.92 m−Gen 4.5) to about 8 m², more typically about 2 m² to about 9 m² or even up to 12 m². Typically, the substrates or carriers, for which the structures, apparatuses, such as cathode assemblies, and methods according to embodiments described herein are provided, are large area substrates as described herein. For instance, a large area substrate or carrier can be GEN 4.5, which corresponds to about 0.67 m² substrates (0.73×0.92 m), GEN 5, which corresponds to about 1.4 m² substrates (1.1 m×1.3 m), GEN 7.5, which corresponds to about 4.29 m² substrates (1.95 m×2.2 m), GEN 8.5, which corresponds to about 5.7 m² substrates (2.2 m×2.5 m), or even GEN 10, which corresponds to about 8.7 m² substrates (2.85 m×3.05 m). Even larger generations such as GEN 11 and GEN 12 and corresponding substrate areas can similarly be implemented.

FIG. 5 shows a schematic view of a deposition chamber 500 according to embodiments. The deposition chamber 500 is adapted for a deposition process, such as a PVD or CVD process. One or more substrates are shown being located on a substrate transport device. According to some embodiments, the substrate support may be movable to allow for adjusting the position of the substrate in the chamber. Particularly for large area substrates as described herein, the deposition can be conducted having a vertical substrate orientation or an essentially vertical substrate orientation. Thereby, the transport device can have lower rollers 522, which are driven by one or more drives 525, e.g. motors. The drives 525 can be connected to a roller 522 by a shaft 523 for rotation of the roller. Thereby, it is possible that one motor 525 drives more than one roller, e.g. by connecting rollers with a belt, a gear system, or the like.

Rollers 524 can be used for support of the substrates in the vertical or essentially vertical position. Typically, the substrates can be vertical or can slightly deviate from the vertical position, e.g. up to 5°. Large area substrates having substrate sizes of 1 m² to 9 m² are typically very thin, e.g. below 1 mm, such as 0.7 mm or even 0.5 mm. In order to support the substrate and to provide the substrates in fixed position, the substrates are provided in a carrier during processing of the substrates. Accordingly, the substrates can be transported by the transport system including, e.g., a plurality of rollers and drives while being supported in a carrier. For example, the carrier with the substrates therein is supported by the system of rollers 522 and rollers 524.

A deposition material source, i.e. a cathode 100 according to embodiments described herein, is provided in the chamber facing the side of the substrate to be coated. The deposition material source 100 provides deposition material 565 to be deposited on the substrate. As shown in FIG. 5 and according to embodiments described herein, the cathode 100 may be a target having target segments and with deposition material thereon.

According to some embodiments, the deposition material, which is indicated by reference numeral 565 during layer deposition, may be chosen according to the deposition process and the later application of the coated substrate. For instance, the deposition material of the source may be a material selected from the group consisting of: a metal, such as aluminum, molybdenum, titanium, copper, or the like, silicon, IZO, IGZO, AZO, SnO, AlSnO, InGaSnO, and other materials, e.g. to form a transparent conductive oxide. Typically, oxide-, nitride- or carbide-layers, which can include such materials, can be deposited by providing the material from the source or by reactive deposition, i.e. the material from the source reacts with elements like oxygen, nitride, or carbon from a processing gas.

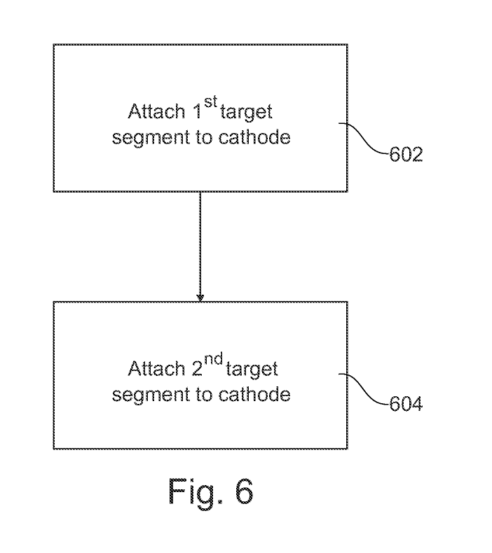

FIG. 6 illustrates an embodiment of a method for manufacturing a rotatable sputter cathode. The method includes, in step 602, attaching a first target segment to a backing tube at a first axial position. In step 604 a second target segment is attached to the backing tube adjacent the first target segment at a second axial position. A step in the outer surface of the first target segment and the outer surface of the second target segment is provided, wherein the step has a height of at least 0.5 mm, particularly of 0.5 mm to 3 mm, more particularly of 1 mm to 1.5 mm. According to typical modifications thereof, in step 602 and step 604 the first target segment and the second target segment can be bonded to the backing tube. According to yet further modifications, which can yield further embodiments, opposing side surfaces of the first target segment and the second target segment are roughened. For example they can be roughened after the grinding of the first target segment and the second target segment. Typically, they can be roughened by beat blasting or the like and to a surface roughness of 10 μm Rmax or above, particularly of 100 μm Rmax or above.

While the foregoing is directed to embodiments of the invention, other and further embodiments of the invention may be devised without departing from the basic scope thereof, and the scope thereof is determined by the claims that follow.

1. A rotatable sputter target configured for rotation around an axis defining an axial direction, comprising:
at least a first target segment and a second target segment forming a target, wherein the first target segment has a first radially outer surface, a first radially inner surface and two first opposing side surfaces,
wherein the second target segment has a second radially outer surface, a second radially inner surface and two second opposing side surfaces,
wherein at least one side surface of the two first opposing side surfaces of the first target segment being provided adjacent to one further side surface of the two second opposing side surfaces of the second target segment has a surface roughness of 10 μm Rmax or above.

2. The target according to claim 1, wherein the first outer radius of the first target segment differs from the second outer radius of the second target segment by 0.5 mm or more, particularly by 0.5 mm to 3 mm.

3. The target according to claim 1, wherein the target has a first axially outer target segment and an opposing axially outer target segment, and wherein at least one of the first target segment and the second target segment is provided in axial direction between the first axially outer target segment and the opposing axially outer target segment.

4. The target according to claim 1, wherein a joint gap is between the first target segment and the second target segment and the joint gap is 0.5 mm or below.

5. The target according claim 1, wherein the length of at least one of the first target segment and the second target segment is 300 mm or above.

6. The target according to claim 1, wherein the first outer radius of the first target segment is provided at a first axial position of the target and the second outer radius of the second target segment is provided at a second axial position of the target, and wherein the first axial position and the second axial position are distant from each other by about 1 mm.

7. The target according to claim 5, wherein the target has a first axially outer target segment and the opposing axially outer target segment have outer radii which are larger than the outer radii of the target segments between the first axially outer target segment and the opposing axially outer target segment.

8. The target according to claim 1, wherein a material of the target is selected from the group consisting of: a ceramic, a metal, ITO, IZO, IGZO, AZO, SnO, AlSnO, InGaSnO, titanium, aluminum, copper, molybdenum, and combinations thereof.

9. The target according to claim 1, wherein the length of the target in the axial direction is 1.5 m or above.

10. A rotatable sputter cathode, comprising:
a backing tube; and
a rotatable sputter target configured for rotation around an axis defining an axial direction, comprising:
at least a first target segment and a second target segment forming a target,
wherein the first target segment has a first radially outer surface, a first radially inner surface and two first opposing side surfaces,
wherein the second target segment has a second radially outer surface, a second radially inner surface and two second opposing side surfaces, wherein at least one side surface of the two first opposing side surfaces of the first target segment is adjacent to one further side surface of the two second side surfaces of the second target segment and a surface roughness of 10 μm Rmax or above.

11. The rotatable sputter cathode according to, claim 13, wherein the target is bonded to the backing tube.

12. The rotatable sputter cathode according to claim 13, wherein the target is a non-bonded target.

13. Method of manufacturing a rotatable sputter cathode, comprising:
attaching a first target segment to a backing tube at a first axial position; and
attaching a second target segment to the backing tube adjacent to the first target segment and at a second axial position,
wherein the first target segment has a first radially outer surface, a first radially inner surface, and two first opposing side surfaces,
wherein the second target segment has a second radially outer surface, a second radially inner surface, and two second opposing side surfaces,
wherein at least one side surface of the two first opposing side surfaces of the first target segment being provided adjacent to one side surface of the two second opposing side surfaces of the second target segment has a surface roughness of 10 μm Rmax or above.

14. The method according to claim 13, wherein a step in the outer surface of a target formed by the first target segment and the second target segment is provided, wherein the step has a height of at least 0.5 mm.

15. The method according to claim 13, wherein opposing side surfaces of the first target segment and the second target segment are roughened after grinding of the first target segment and the second target segment.

16. The target according to claim 1, wherein the two first opposing side surfaces are two first opposing ring-shaped side surfaces.

17. The target according to claim 1, wherein the two second opposing side surfaces are two second opposing ring-shaped side surfaces.

18. The target according to claim 1, wherein the surface roughness is 100 μm Rmax or above.

19. The method according to claim 16, wherein the two first opposing side surfaces are two first opposing ring-shaped side surfaces and/or wherein the two second opposing side surfaces are two second opposing ring-shaped side surfaces.

20. The method according to claim 16, wherein the surface roughness is 100 μm Rmax or above.
